(19) United States
(12) Patent Application Publication
(10) Pub. No.: US 2009/0273276 A1
(43) Pub. Date: Nov. 5, 2009

(54) Organic electroluminescence element

(75) Inventor: Masanori Maeda, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/974,671

(22) Filed: Oct. 15, 2007

(30) Foreign Application Priority Data
Oct. 16, 2006 (JP) 2006-281681

(51) Int. Cl. H01J 1/63

(52) U.S. Cl. 313/504

(57) ABSTRACT

Provided is an organic EL elements in which an anode, a hole injection layer, a hole transport layer, an emissive layer, an electron transport layer, a cathode are stacked up on a substrate. An electron transporting material which is not a metal complex and which has a work function at HOMO level exceeding 5.7 eV is used as a host material of the emissive layer. Accordingly, the energy-barrier difference between the hole transport layer and the emissive layer, or that between the hole injection layer and the emissive layer can be made greater than that in a conventional organic EL element. This enhances the hole-blocking performance for the organic EL element of the present invention, so that the carrier balance between the electrons and the holes in the emissive layer can be improved.

### CROSS REFERENCE TO RELATED APPLICATIONS AND INCORPORATION BY REFERENCE

This application is based upon and claims the benefit of prior Japanese Patent Application P2006-281681 filed on Oct. 16, 2006; the entire contents of which are incorporated by reference herein.

### BACKGROUND OF THE INVENTION

1. Field of the Invention

The present invention relates to an organic EL element (organic electroluminescence element) with enhanced luminous efficacy.

2. Description of the Related Art

In a conventional-type organic EL element, organic layers are formed so as to sandwich an emissive layer. The organic layers thus formed facilitate the carriers such as electrons and holes to be injected into the emissive layer. Furthermore, an electrode is formed at the outer side of each of the organic layers.

In the structure of a well-known example of organic EL elements, an anode 22, a hole injection layer 23, a hole transport layer 24, an emissive layer 25, an electron transport layer 26, and a cathode 27 are stacked up in this order on top of a glass substrate. FIG. 5 shows an energy diagram for the above-mentioned structure. Note that the numbers inscribed for the energy bands in FIG. 5 represent the work functions with their unit being eV.

The electron transport layer 26 is used for making the electrons transfer smoothly to the emissive layer 25, and for preventing the holes that have entered the emissive layer 25 from moving into the electron transport layer 26. In contrast, the hole transport layer 24 is used for making the holes transfer smoothly to the emissive layer 25, and for preventing the electrons that have entered the emissive layer 25 from moving into the hole transport layer 24.

In addition, the hole injection layer 23 is provided for facilitating the injection of the holes into the emissive layer 25 by lowering the energy barrier that exists between the emissive layer 25 and the anode 22. The layers of the organic EL element shown in FIG. 5 are individually formed by the vacuum deposition method.

Incidentally, an aluminum-quinolinol complex (Alq₃) is commonly used as the host material for the emissive layer 25 of a conventional-type organic EL element. The use of the aluminum-quinolinol complex has become a mainstream for the art as being pointed out in Yuki EL Disupurei no Saishin Gijyutu Doko (Latest Technological Developments in Organic EL Display) Joho Kiko Co., Ltd., 25th of April, 2003, pp. 102 to 107. With the use of the aluminum-quinolinol complex, the emissive layer 25 has an energy bandwidth ranging from 3.0 eV to 5.7 eV. In addition, use of a transparent electrode, such as ITO, for the anode 22 makes the work function at the HOMO level for the hole transport layer 24 in the energy band shown in FIG. 5 be around 5.3 eV.

In the conventional-type organic EL element, however, some of the holes injected from the anode 22 are captured within the emissive layer 25 and are used for emitting lights, but quite a number of holes wastefully pass through the emissive layer 25 towards the cathode 27. This is because, as shown in FIG. 5, the energy-barrier difference between the emissive layer 25 and the hole transport layer 24 is only 0.4 eV for the HOMO-level side. To put it other way, the emissive layer 25 is capable of blocking the holes only insufficiently. As a result, quite a number of holes pass through the emissive layer 25 to reach the cathode 27.

In this case, within the emissive layer 25, the carriers—the holes and the electrons—cannot maintain a sufficient balance any longer. The proportion of the holes that can be recombined with the electrons becomes lower. The energy dissipation of the generated excitons is increased, and this leads to lower luminous efficacy and degraded color purity.

The present invention is made to address the above-described problems, and aims to provide an organic EL element capable of reducing the number of holes that pass through the emissive layer as well as of improving the luminous efficacy and the color purity.

### SUMMARY OF THE INVENTION

A first aspect of the present invention provides an organic EL element characterized in that a host material of an emissive layer is a material which is not a metal complex. In addition, the material used for this purpose is an electron transporting material with a work function at the HOMO level exceeding 5.7 eV.

A second aspect of the present invention provides an organic EL element of the first aspect characterized additionally in that the electron transporting material has an electron mobility of 10⁻⁴ cm²/(V·S) or higher.

A third aspect of the present invention provides an organic EL element of the first aspect characterized additionally in that at least any one of a hole transport layer and a hole injection layer is formed between an anode and the emissive layer.

According to the present invention, an electron transporting material which is not a metal complex and which has a work function at the HOMO level exceeding 5.7 eV is used as the host material of the emissive layer. Consequently, the energy-barrier difference between the emissive layer and the organic layer that is adjacent to the emissive layer from the anode side can be made larger, and this, in turn, enhances the hole-blocking performance. As a result, higher color purity and higher luminous efficacy can be achieved.

### BRIEF DESCRIPTION OF DRAWINGS

FIG. 1 is an energy diagram for an organic EL element according to the present invention.

FIG. 2 is a drawing illustrating an example of the structure of the organic EL element.

FIG. 3 is a table showing the measurement results obtained by comparing the organic EL element according to the present invention with a conventional-type organic EL element.

FIG. 4 is an energy diagram in a case where an electron transport layer is made of the same material that is used as the host material of an emissive layer.

FIG. 5 is an energy diagram for a conventional-type organic EL element.

### DETAILED DESCRIPTION OF THE INVENTION

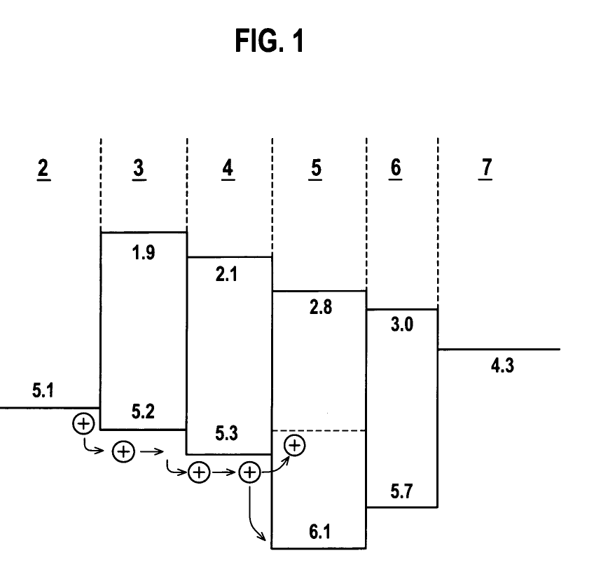

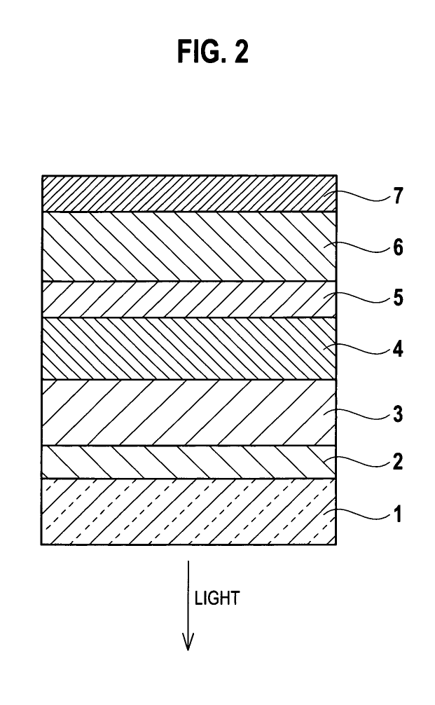

An embodiment of the present invention will be described with reference to the accompanying drawings. FIG. 2 illustrates a sectional structure of an organic EL element according to the present invention. FIG. 1 shows an energy diagram for the organic EL element of FIG. 2.

An anode 2, a hole injection layer 3, a hole transport layer 4, an emissive layer 5, an electron transport layer 6, a cathode 7 are stacked up on top of a substrate 1. The emissive layer 5 is formed, for example, by doping a fluorescent dye into a luminescence material (host material) so as to emit light of a particular color within the visible light range (400 nm to 750 nm) . For example, to emit green light, an organic material obtained by doping coumarin C545T or quinacridone as a guest material into an aluminum-quinolinol complex (Alq₃) is used as a material for the emissive layer 5.

The electron transport layer 6 is made of an aluminum-quinolinol complex or the like while the cathode 7 is made of a metal, such as aluminum. The hole transport layer 4 is made of naphthyl-phenyl benzidine (NPB), a triphenylamine derivative (TPD), NPD, or the like. The hole injection layer 3 is made of m-MTDATA, phthalocyanines, such as CuPc, a polythiophene, or the like. A transparent substrate made of, for example, glass is used as the substrate 1. A transparent electrode of, for example, ITO is used as the anode 2. The light emitted by the emissive layer 5 is taken out in a direction indicated by the arrow in FIG. 2.

The organic EL element of the present invention was fabricated as follows: the substrate 1 was made of a glass substrate; the anode 2, ITO; the hole injection layer 3, a polythiophene; the hole transport layer 4, a TPD; the electron transport layer 6, an aluminum-quinolinol complex; and the cathode 7, aluminum (Al). In addition, as the host material of the emissive layer 5, TR-E314, which is a sort of electron transporting materials and which is not a metal complex, was used. For the dopants to be the guest materials, rubrene was used as an assist dopant, and RD3 was used as an emission dopant.

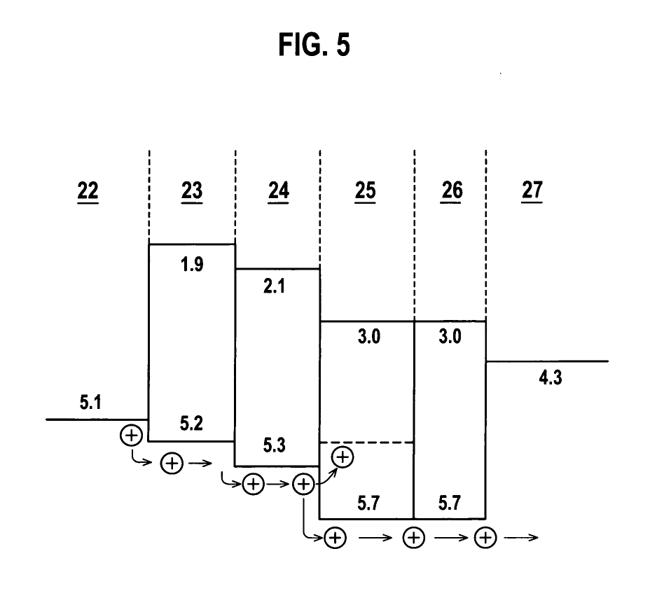

With the layers in FIG. 2 formed as described above, an energy diagram shown in FIG. 1 was obtained. A comparison of FIG. 1 and FIG. 5 shows the same energy-band configuration except for the emissive layer. For the emissive layer 5, TR-E314, which is a sort of electron transporting materials, was used as the host material. Consequently, the bandwidth became larger, and the 6.1-eV work function at the HOMO level made the energy-barrier difference with the hole transport layer 4 be as large as 0.8 eV.

With such a large energy barrier difference, most of the holes injected from the anode 2 and advancing towards the emissive layer 5 were captured within the emissive layer 5. Lower proportion of the holes successfully passed through the emissive layer 5. Accordingly, the carrier balance between the electrons and the holes within the emissive layer 5 was improved. This resulted in a higher proportion of recombination and in less energy dissipation of the generated excitons. As a result, the luminous efficacy and color purity were improved.

On the other hand, in the conventional-type organic EL element, an aluminum-quinolinol complex, which is a sort of electron transporting materials, is used as the host material of the emissive layer 25. The aluminum-quinolinol complex is, however, a metal complex, so that the emissive layer 25 only poorly blocks the holes and allows a higher proportion of the holes to pass therethrough.

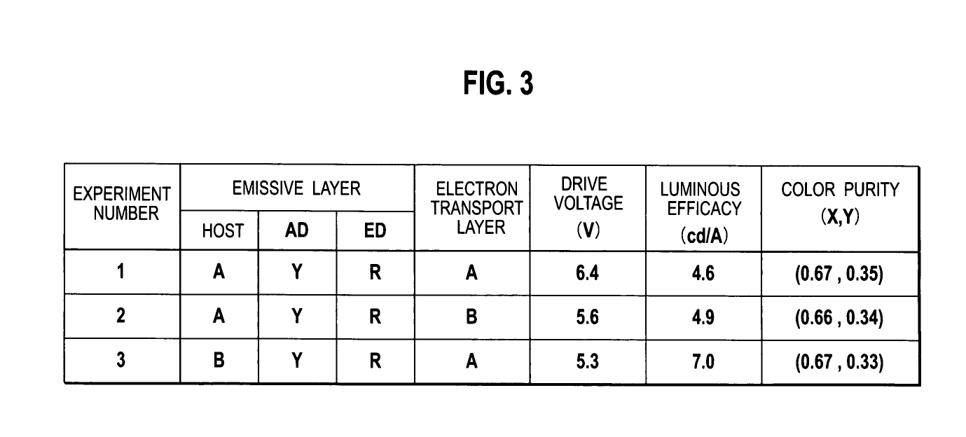

FIG. 3 shows performance comparisons of the organic EL element of the present invention and organic EL elements with different configurations. Experiment number 3 corresponds to the organic EL element of the present invention with the above-described configuration. Experiment number 1 corresponds to a conventional-type element with the configuration shown in FIG. 5. Experiment numbers 1 and 3 had a common configuration of the anode, the hole injection layer, the hole transport layer, the electron transport layer, the cathode. To put it other way, experiment numbers 1 and 3 had the same configuration except for the emissive layer.

The emissive layer was composed of a host material (“Host” in FIG. 3) and two kinds of dopants as guest materials. The two kinds of dopants were made up of an assist dopant (“AD” in FIG. 3) and an emission dopant (ED in FIG. 3). In FIG. 3, “A,” “Y,” “R,” and “B” are organic materials. Specifically, “A” is an aluminum-quinolinol complex (Alq₃); “Y,” rubrene; “R,” RD3, which is a red-color dopant; and “B,” TR-E314.

Here, amongst the constituents of the emissive layer, the only difference between the experiment numbers 1 and 3 was the host material. As having been described with reference to FIG. 1, the energy-barrier difference at the HOMO level between the hole transport layer 4 and the emissive layer 5 became 0.8 eV. Accordingly, experiment number 3 showed significantly improved hole blocking performance. As a consequence, both the color purity and the luminous efficacy were improved as shown in FIG. 3. In addition, experiment number 3 had a lowered drive voltage.

In addition, there is a difference between an aluminum-quinolinol complex (organic material A) and TR-E314 (organic material B) not only in the hole-blocking performance but also in the electron mobility. The electron mobility of the aluminum-quinolinol complex is approximately 10⁻⁵ cm²/(V·s) while that of TR-E314 is approximately 10⁻⁴ cm²/(V·s) or higher. In short, the electron mobility of TR-E314 is higher than that of the aluminum-quinolinol complex by not less than a single digit.

Ordinarily, the hole mobility is larger than the electron mobility by approximately double digits, so that the holes can reach the emissive layer earlier than the electrons. Consequently, fewer electrons can reach the emissive layer, and thus the balance between the electrons and the holes within the emissive layer is lost. Many holes that cannot find electrons to be recombined with accumulate at the interface between the hole transport layer and the emissive layer. The accumulated holes continuously oxidize organic molecules within the emissive layer, and the emissive layer stays in a radical-cation state for a longer time. Hence organic molecules in the emissive layer 25 tend to be degraded. Such degradation can be suppressed by selecting, as described above, an electron transporting material which is not a metal complex and which has larger electron mobility.

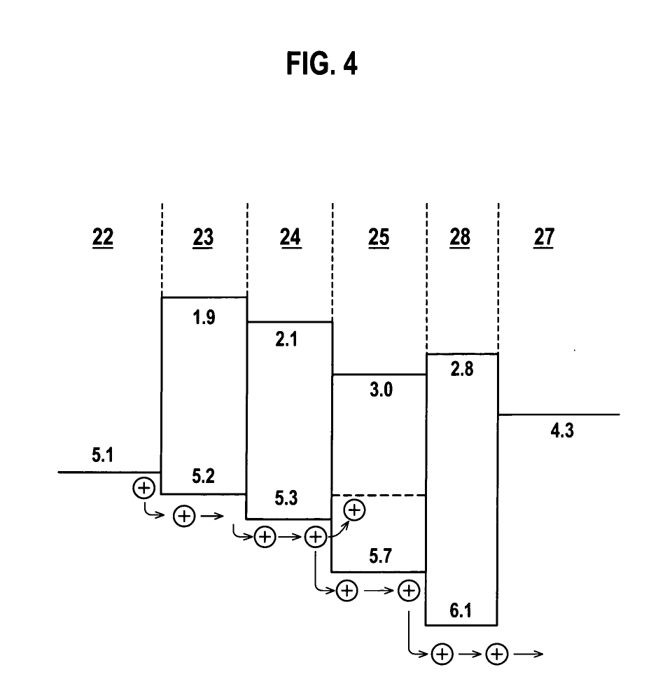

As to the constituent materials of the emissive layer, the experiment number 2 had the same materials that the experiment number 1 shown in the conventional-type configuration shown in FIG. 5 had. The experiment number 2, however, differed from the experiment number 1 in the material used for the electron transport layer. Specifically, the material of the electron transport layer for the experiment number 2 was not an aluminum-quinolinol complex (Alq₃) but TR-E314. As FIG. 1 shows, the energy bandwidth of TR-E314 ranged from 2.8 eV to 6.1 eV. When such a bandwidth was applied to the electron transport layer 26 shown in FIG. 5, an energy diagram shown in FIG. 4 was obtained.

The energy-barrier difference in FIG. 4 between the hole transport layer 24 and the emissive layer 25 was 0.4 eV, which is equivalent to the corresponding value in FIG. 5. However, the energy-barrier difference between the emissive layer 25 and the electron transport layer 28 in FIG. 4 was 0.4 eV, which is higher than the corresponding value in FIG. 5. Accordingly, the holes were blocked by the electron transport layer 28. As a consequence, the experiment number 2 had higher luminous efficacy and a lower drive voltage than that of the experiment number 1.

Nevertheless, the energy-barrier difference between the emissive layer 25 and the electron transport layer 28 was as small as 0.4 eV, so that the electron transport layer 28 was not able to block the holes sufficiently. A considerable number of holes successfully passed through towards cathode 27, so that the experiment number 2 had lower luminous efficacy, higher drive voltage, poorer color purity than the outcomes of the experiment number 3.

It should be noted that electron transporting materials that are not a metal complex includes, besides the ones mentioned above, oxadiazole derivatives, stilbene derivatives, triazine derivatives, and the like. When an organic material that has a larger work function at the HOMO level than 5.7 eV for the aluminum-quinolinol complex, and an electron mobility equivalent to or higher than that of the aluminum-quinolinol complex is selected to use as the host material of the emissive layer 5, hole-blocking effects that are similar to those in the case of TR-E314 can be expected.

Needless to say, the present invention can include various embodiments and the like that are not described in this specification. The technical scope of the present invention should be defined by the following claims relevant to the descriptions thus far made.

What is claimed is:

1. An organic electroluminescence element comprising:
a host material of an emissive layer, the host material being made of a material that is not a metal complex;
wherein the host material is an electron transporting material with a work function at HOMO level exceeding 5.7 eV.

2. The organic electroluminescence element of claim 1, wherein:
the electron transporting material has an electron mobility of 10⁻⁴ cm²/(V·s) or higher.

3. The organic EL element of claim 1, wherein:
at least any one of a hole transport layer and a hole injection layer is formed between an anode and the emissive layer.
